(19) United States
(12) Patent Application Publication
(10) Pub. No.: US 2013/0105901 A1
(43) Pub. Date: May 2, 2013

(54) SEMICONDUCTOR DEVICE WITH METAL GATE ELECTRODE AND HIGH-K DIELECTRIC MATERIAL AND METHOD FOR FABRICATING THE SAME

(71) Applicants: Woo-Young PARK, Gyeonggi-do (KR); Kee-Jeung Lee, Gyeonggi-do (KR); Yun-Hyuck Ji, Gyeonggi-do (KR); Seung-Mi Lee, Gyeonggi-do (KR)

(72) Inventors: Woo-Young PARK, Gyeonggi-do (KR); Kee-Jeung Lee, Gyeonggi-do (KR); Yun-Hyuck Ji, Gyeonggi-do (KR); Seung-Mi Lee, Gyeonggi-do (KR)

(21) Appl. No.: 13/339,787

(22) Filed: Dec. 29, 2011

(30) Foreign Application Priority Data
Oct. 31, 2011 (KR) 10-2011-0111831

(51) Int. Cl. H01L 27/088; H01L 21/28; H01L 21/336; H01L 29/772

(52) U.S. Cl. 257/368; 257/410; 257/288; 438/591; 438/287; 257/E29.242; 257/E27.06; 257/E21.19; 257/E21.409

(57) ABSTRACT

A semiconductor device includes a gate stacked structure including a gate dielectric layer over a semiconductor substrate, a metal layer formed over the gate dielectric layer, and a capping layer formed over the metal layer, where the capping layer includes a chemical element with a higher concentration at an interface between the capping layer and the metal layer than another region of the capping layer and the chemical element is operable to control an effective work function (eWF) of the gate stacked structure.

### CROSS-REFERENCE TO RELATED APPLICATIONS

The present application claims priority of Korean Patent Application No. 10-2011-0111831, filed on Oct. 31, 2011, which is incorporated herein by reference in its entirety.

### BACKGROUND

1. Field

Exemplary embodiments of the present invention relate to a semiconductor device, and more particularly, to a gate stacked structure with a metal gate electrode and a high-k dielectric material and a semiconductor device including the same.

2. Description of the Related Art

Generally, in a complementary metal oxide semiconductor (CMOS) integrated circuit, an N-channel metal-oxide-semiconductor (NMOS) and a P-channel metal-oxide-semiconductor (PMOS) include a gate dielectric layer formed of silicon oxide (SiO₂) or silicon oxynitride (SiON). Here, an N-type polysilicon layer is used as a gate electrode of the NMOS, and a P-type polysilicon layer is used as a gate electrode of the PMOS.

As a semiconductor device is desired to have a high integration degree, high driving speed, and low power consumption, a drain current is to be large enough, and an off-current is to be increased despite a thickness reduction of a gate dielectric layer.

To address such features, a method for using a material with a lager dielectric constant than silicon oxide and silicon oxynitride as the gate dielectric layer is being developed. Examples of the material include a high-k dielectric material which has a dielectric constant larger than 3.9, exhibits excellent thermal stability at high temperature and has other useful features. However, the high-k dielectric material has compatibility issues such as Fermi-level pinning and gate depletion which may occur at the interface with a polysilicon layer.

As a method to address such features, a gate stacked structure having a metal-inserted polysilicon (MIPS) structure is being developed. The gate stacked structure having the MIPS structure includes a metal layer inserted between a gate dielectric layer and a polysilicon layer. When the gate stacked structure having the MIPS structure is used, the gate depletion and a threshold voltage variation due to fixed charges may be controlled.

However, when the metal layer is used as the gate electrode, it is difficult to control a work function (WF). In particular, an effective work function (eWF) of the metal layer may be degraded by a subsequent high-temperature annealing process for source/drain formation. As a countermeasure against the degradation, an oxide capping layer has been used to control a threshold voltage using the electro-negativity principle. However, the oxide capping layer may increase the number of processes, thereby increasing a production cost.

### SUMMARY

An embodiment of the present invention is directed to an NMOS with a gate stacked structure capable of obtaining an appropriate threshold voltage, a semiconductor device, and a method for fabricating the same.

In accordance with an embodiment of the present invention, a semiconductor device includes: a gate stacked structure comprising a gate dielectric layer formed over a semiconductor substrate, a metal layer formed over the gate dielectric layer, and a capping layer formed over the metal layer, wherein the capping layer includes a chemical element with a higher concentration at an interface between the capping layer and the metal layer than another region of the capping layer and the chemical element is operable to control an effective work function (eWF) of the gate stacked structure.

In accordance with another embodiment of the present invention, a semiconductor device includes an N-channel metal-oxide-semiconductor (NMOS) gate stacked structure and a P-channel metal-oxide-semiconductor (PMOS) gate stacked structure which are isolated from each other and formed over a semiconductor substrate. The NMOS gate stacked structure includes a gate dielectric layer, a metal layer over the gate dielectric layer and a capping layer over the metal layer. The capping layer includes a chemical element having a higher concentration at an interface between the capping layer and the metal layer than another region of the capping layer, and the chemical element is operable to control an effective work function (eWF) of the NMOS gate stacked structure.

In accordance with yet another embodiment of the present invention, an NMOS includes: a semiconductor substrate having an N-channel; a gate stacked structure including a gate dielectric layer formed over the N-channel, a metal layer formed over the gate dielectric layer, and a capping layer including a higher concentration of boron at an interface between the metal layer and the capping layer than another region of the capping layer, wherein the boron is operable to control an effective work function (eWF) of the gate stacked structure.

In accordance with still another embodiment of the present invention, a method for fabricating a semiconductor device includes: forming a gate dielectric layer over a semiconductor substrate; forming a metal layer over the gate dielectric layer; forming a capping layer over the metal layer, the capping layer including a chemical element for controlling an effective work function (eWF); forming a gate stacked structure by etching the capping layer, the metal layer, and the gate dielectric layer; and performing annealing to form a higher concentration of the chemical element at an interface between the capping layer and the metal layer than another region of the capping layer.

In accordance with still another embodiment of the present invention, a method for fabricating a semiconductor device includes: forming a gate dielectric layer over a semiconductor substrate; forming a metal layer over the gate dielectric layer; forming a capping layer over the metal layer, wherein the capping layer includes a chemical element for controlling an effective work function (eWF); forming a gate stacked structure by etching the capping layer, the metal layer, and the gate dielectric layer; forming a source/drain by implanting impurities into the substrate; and performing annealing to form a higher concentration of the chemical element at an interface between the capping layer and the metal layer than another region of the capping layer.

### BRIEF DESCRIPTION OF THE DRAWINGS

FIG. 1 is a diagram illustrating a gate stacked structure in accordance with a first embodiment of the present invention.

FIGS. 2A to 2E are diagrams illustrating a method for fabricating an NMOS in accordance with the first embodiment of the present invention.

FIG. 3 is a diagram illustrating a gate stacked structure in accordance with a modification of the first embodiment of the present invention.

FIG. 4 is a diagram illustrating a gate stacked structure in accordance with a second embodiment of the present invention.

FIGS. 5A to 5F are diagrams illustrating a method for fabricating an NMOS in accordance with the second embodiment of the present invention.

FIG. 6 is a diagram illustrating a CMOS integrated circuit including the NMOS in accordance with the embodiments of the present invention.

FIG. 7 is a graph showing variations in a flat band voltage in accordance with the embodiments of the present invention.

FIG. 8 is a graph showing a secondary ion mass spectroscopy (SIMS) analysis result which is obtained after an annealing process is performed on the gate stacked structures in accordance with the embodiments of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

An electrical characteristic such as an effective work function (eWF) is evaluated by C-V (capacitance-voltage) and I-V (current-voltage) measurements. In the embodiments of the present invention, an eWF is estimated/acquired from a flat band by the C-V measurement of a gate electric layer and a gate electrode. An eWF of a gate electrode material may be affected by fixed charges of the gate dielectric layer, a dipole formed at an interface, Fermi level pinning and so on. This is different from a unique WF of the gate electrode material.

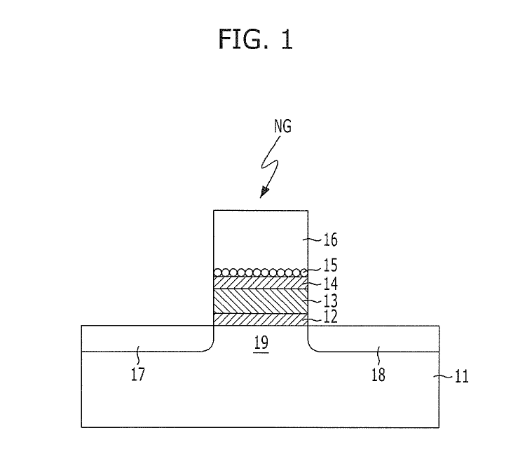

FIG. 1 is a diagram illustrating a gate stacked structure in accordance with a first embodiment of the present invention. FIG. 1 illustrates a gate stacked structure of an NMOS.

Referring to FIG. 1, a substrate 11 includes a transistor region. Here, the transistor region is where an N-channel metal oxide semiconductor field-effect transistor (NMOSFET, hereafter referred to as NMOS) is formed.

A gate stacked structure NG is formed over a substrate 11. The gate stacked structure NG includes a gate dielectric layer 13, a metal layer 14, and a capping layer 16, which are sequentially stacked. The gate stacked structure NG further includes an interfacial layer 12 between the gate dielectric layer 13 and the substrate 11. The interfacial layer 12 may include silicon oxide.

The substrate 11 may include substrates formed of silicon, germanium, and silicon germanium, but are not limited thereto. Furthermore, the entire substrate 11 or a part of the substrate 11 may be placed under strain (for example, so as cause deformation).

The gate stacked structure NG may be described in detail as follows.

First, the gate dielectric layer 13 includes a material having a high dielectric constant (hereafter, referred to as a high-k dielectric). The high-k dielectric has a larger dielectric constant than the dielectric constant (about 3.9) of silicon oxide (SiO₂) which is generally used as a gate dielectric layer. Furthermore, the high-k dielectric layer has a considerably larger physical thickness and a smaller equivalent oxide thickness (EOT) than silicon oxide. The gate dielectric layer 13 includes a metal containing material such as metal oxide, metal silicate, or metal silicate nitride. The metal oxide includes oxide containing a metal such as hafnium (Hf), aluminum (Al), lanthanum lanthanum (La), or zirconium (Zr). The metal oxide may include hafnium oxide (HfO₂), aluminum oxide (Al₂O₃), lanthanum oxide (LaO₂), zirconium oxide (ZrO₂) or a combination thereof. The metal silicate includes silicate containing a metal such as Hf or Zr. The metal silicate may include hafnium silicate (HfSiO), zirconium silicate (ZrSiOₓ), or a combination thereof. The metal silicate nitride is a material obtained by a reaction of nitrogen with the metal silicate. According to an example, the gate dielectric layer 13 may include the metal silicate nitride. The metal silicate nitride may include hafnium silicate nitride (HfSiON). When the gate dielectric layer 13 is formed of metal silicate nitride, the dielectric constant may be increased, and crystallization may be suppressed during a subsequent thermal process. According to an example, the gate dielectric layer 13 may be formed of a material having a dielectric constant of 9 or more.

The metal layer 14 includes a metallic material such as metal, metal nitride, or metal carbide. For example, tungsten (W), tantalum (Ta), aluminum (Al), ruthenium (Ru), platinum (Pt), titanium nitride (TiN), tantalum nitride (TaN), titanium carbide (TiC), tantalum carbide (TaC), and a mixture thereof may be used. Furthermore, the metal layer 14 may include multi-layers of the above-described materials. The metal layer 14 becomes a metal gate electrode of the NMOS.

The capping layer 16 serves to prevent the oxidation of the metal layer 14. The capping layer 16 includes polysilicon or silicon germanium (SiGe). The capping layer 16 includes a plurality of chemical elements 15 concentrated at the interface with the metal layer 14 (that is, chemical elements 15 have a higher concentration at the interface than in the rest of the capping layer 16). The plurality of chemical elements 15 serve to reduce the eWF of the gate stacked structure NG. The plurality of chemical elements 15 include boron. The plurality of chemical elements 15 may have such a high density as to form one layer at the interface between the capping layer 16 and the metal layer 14. When the plurality of chemical elements 15 are distributed at such a high density, the eWF reduction effect is further increased. The plurality of chemical elements 15 may have a concentration of 10²⁰ to 10²² atoms/cm².

Inside the substrate 11, a source and drain 17 and 18 are formed. The source and drain 17 and 18 have N-type impurities implanted thereto. An N-channel 19 is formed in the substrate 11 under the gate stacked structure NG between the source and drain 17 and 18.

The gate stacked structure of FIG. 1 becomes a gate stacked structure of the NMOS. The gate stacked structure has a MIPS structure including a high-k dielectric material and a metal gate.

In the gate stacked structure NG, the plurality of chemical elements 15 are concentrated at the interface between the metal layer 14 and the capping layer 16. The plurality of chemical elements 15 include boron. The chemical elements 15 are concentrated at an interface with the metal layer 15 to thereby reduce the eWF of the gate stacked structure NG. Specifically, as boron is concentrated at the interface between the metal layer 14 and the capping layer 16, the eWF of the gate stacked structure NG may be reduced to obtain an eWF suitable for the NMOS, and the threshold voltage may be controlled for the NMOS. Here, the eWF suitable for the NMOS has a smaller value than 4.5 eV.

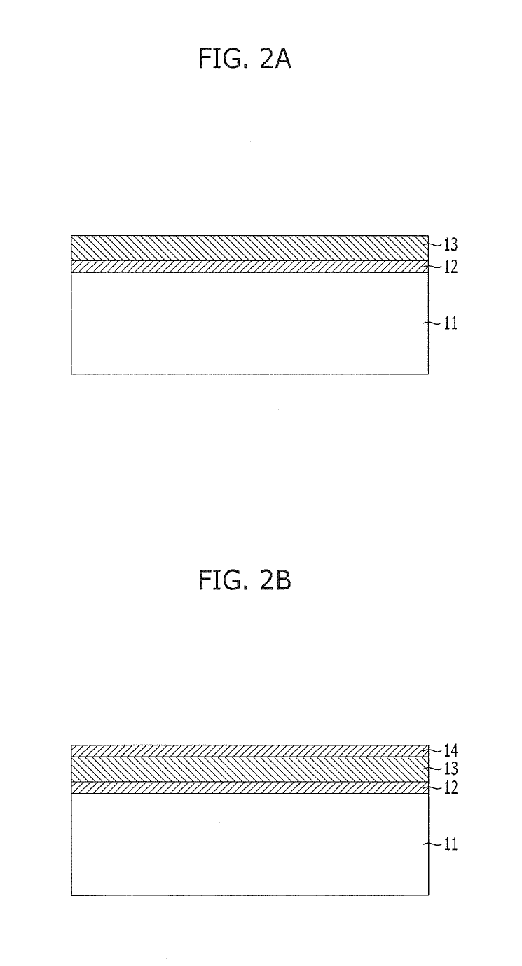

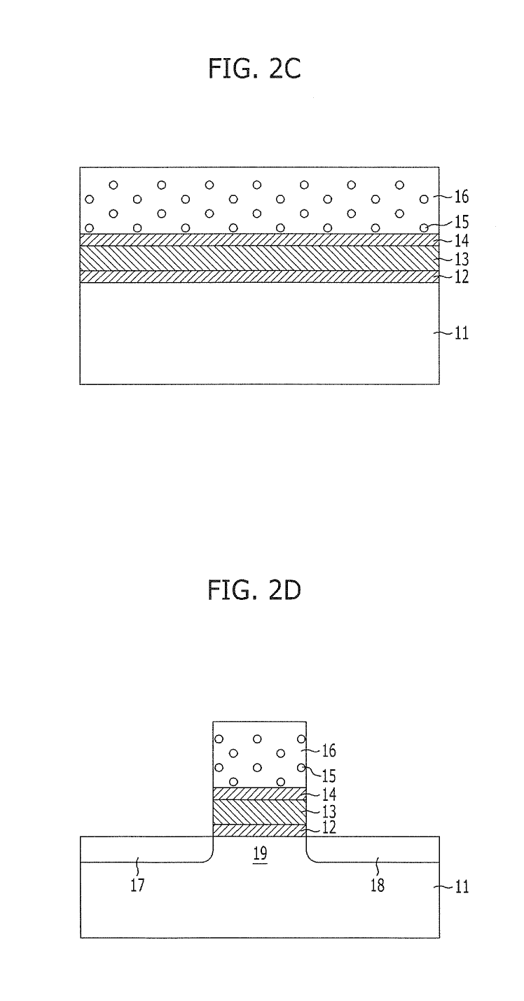

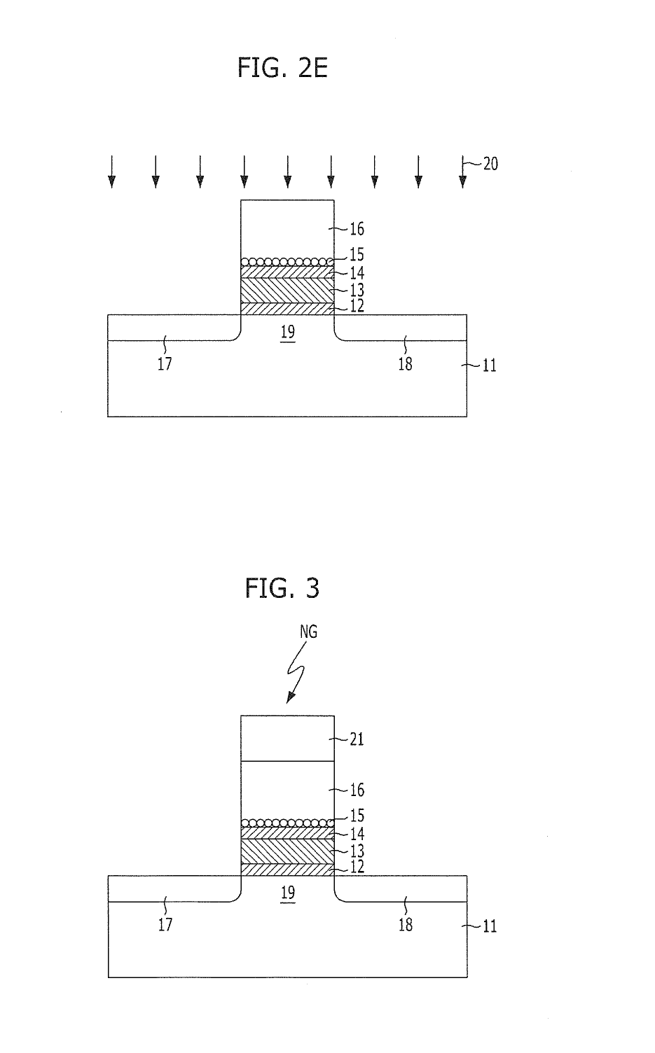

FIGS. 2A to 2E are diagrams illustrating a method for fabricating the semiconductor device in accordance with the first embodiment of the present invention. In the first embodiment of the present invention, an NMOS fabrication method will be described. The NMOS fabrication method is performed by a first gate process. The first gate process refers to a process in which annealing is performed after gate patterning is completed, when fabricating a semiconductor device having a high-k dielectric material and a metal gate electrode. The present invention is not limited to the NMOS, but may be applied to a method for fabricating an N-channel FET.

Referring to FIG. 2A, a substrate 11 is prepared. The substrate 11 is where an NMOS is formed. The substrate 11 may include substrates formed of silicon, germanium, and silicon germanium, but are not limited thereto. Here, the entire substrate 11 or a part of the substrate 11 may be placed under strain. Furthermore, although not illustrated, the substrate 11 may include a well which is formed through any reasonably suitable well formation process. Since the substrate 11 includes a region where the NMOS is formed, the well is a P-type well. In order to form a P-type well, P-type impurities such as boron may be implanted into the substrate 11. Furthermore, although not illustrated, an N-channel region may be formed through any reasonably suitable channel ion implantation process after the well formation process. In order to form the N-channel region, N-type impurities such as phosphorus (P) or arsenic (As) may be implanted into the substrate 11.

Subsequently, the gate dielectric layer 13 is formed over the substrate 11. The gate dielectric layer 13 includes at least a high-k dielectric material. Furthermore, an interfacial layer 12 may be further formed between the substrate 11 and the gate dielectric layer 13.

The gate dielectric layer 13 is formed by the following method.

First, native oxide on the surface of the substrate 11 is removed through a cleaning process. The cleaning process is performed using a solution containing HF. As the cleaning process is performed, the native oxide on the surface of the substrate 11 is removed, and a dangling bond on the surface of the substrate 11 is also passivated with hydrogen. Therefore, the native oxide is suppressed from growing before a subsequent process is performed.

Subsequently, an interfacial layer 12 is formed. The interfacial layer 12 includes a dielectric material, for example, silicon oxide SiO₂ or silicon oxynitride (SiON). The interfacial layer 12 serves to improve an interfacial characteristic between the substrate 11 and the gate dielectric layer 13, thereby enhancing electron mobility characteristics.

Next, the gate dielectric layer 13 is formed. The gate dielectric layer 13 includes a high-k dielectric material (hereafter, referred to as a high-k dielectric). The high-k dielectric material has a larger dielectric constant than the dielectric constant (about 3.9) of silicon oxide (SiO₂), which is generally used as a gate dielectric layer. Furthermore, the high-k dielectric has a considerably larger physical thickness and a smaller equivalent oxide thickness (EOT) than silicon oxide. The gate dielectric layer 13 may include a material having a larger dielectric constant than the interfacial layer 12.

The high-k dielectric material used as gate dielectric layer 13 includes a metal containing material such as metal oxide, metal silicate, or metal silicate nitride. The metal oxide includes oxide containing a metal such as Hf, Al, La, or Zr. The metal oxide may include hafnium oxide (HfO₂), aluminum oxide (Al₂O₃), lanthanum oxide (LaO₂), zirconium oxide (ZrO₂), or a combination thereof. The metal silicate includes silicate containing a metal such as Hf or Zr. The metal silicate may include hafnium silicate (HfSiO), zirconium silicate (ZrSiOₓ), or a combination thereof. The metal silicate nitride is a material obtained by a reaction of nitrogen with metal silicate. The metal silicate nitride may include hafnium silicate nitride (HfSiON). When the metal silicate nitride is used to form the gate dielectric layer 13, the dielectric constant may be increased, and crystallization may be suppressed during a subsequent thermal process. The formation process of the gate dielectric layer 13 may be performed by, for example, any reasonably suitable deposition technology for depositing a material. For example, the deposition technology may include chemical vapor deposition (CVD), low-pressure CVD (LPCVD), plasma-enhanced CVD (PECVD), metal-organic CVD (MOCVD), atomic layer deposition (ALD), plasma-enhanced ALD (PEALD), and so on. According to an example, the PEALD may be used to form a uniform thin film.

According to an example, the gate dielectric layer 13 may be formed of a material having a dielectric constant of 9 or more. Furthermore, the gate dielectric layer 13 may be formed of a Hf-based material. Here, the Hf-based material includes hafnium oxide (HfO₂), hafnium silicate (HfSiO), and hafnium silicate nitride (HfSiON).

Referring to FIG. 2B, a metal layer 14 is formed over the gate dielectric layer 13. The metal layer 14 may be formed over the entire surface of the substrate 11 including the gate dielectric layer 13. The metal layer 14 becomes a metal gate electrode of the NMOS. The metal layer 14 includes a metallic material (that is, metal, metal nitride, or metal carbon nitride). For example, titanium nitride (TiN), titanium carbon nitride (TiCN), titanium aluminum nitride (TiAlN), titanium silicon nitride (TiSiN), tantalum nitride (TaN), tantalum carbon nitride (TaCN), tantalum silicon nitride (TaSiN), tantalum titanium nitride (TaTiN), titanium silicide (TiSi), hafnium nitride (HfN), and a mixture thereof may be used for the metal layer 14. Furthermore, the metal layer 14 may include multi-layers of the above-described materials. The metal layer 14 is formed to a thickness of 0.1 nm˜4 nm. When the metal layer 14 is formed to such a small thickness, eWF may be reduced.

Referring to FIG. 2C, a capping layer 16 containing a plurality of chemical elements 15 for controlling an eWF is formed over the metal layer 14. The capping layer 16 serves as an oxidation prevention layer to prevent the oxidation of the metal layer 14.

The plurality of chemical elements 15 include elements to reduce the eWF of the gate stacked structure. The capping layer 16 includes a material preventing the oxidation of the metal layer 14. The capping layer 16 includes a silicon containing layer. The capping layer 16 includes polysilicon or silicon germanium (SiGe). Since the chemical elements 15 are elements to reduce the eWF, the capping layer 16 includes polysilicon or SiGe doped with the plurality of chemical elements 15. The plurality of chemical elements 15 may include boron.

Therefore, the capping layer 16 includes boron-doped polysilicon or boron-doped SiGe.

The plurality of chemical elements 15 may be in-situ doped when the capping layer 16 is formed. For example, when the capping layer 16 includes SiGe, boron containing gas is used to in-situ dope boron during deposition of SiGe for the capping layer 16. As such, since boron is used as a dopant during the deposition of SiGe, boron within the capping layer 16 may have a uniform concentration. In another embodiment, during the deposition of SiGe for the capping layer 16, boron containing gas may be used to in-situ dope boron such that the capping layer has a concentration gradient of boron.

The capping layer 16 is deposited at a temperature of 450° C. or less in a furnace. In order to dope the plurality of chemical elements 15, a silicon source, a germanium source, or a boron containing source may be used as reaction gas during the deposition of the capping layer 16. The silicon source includes SiH₄, the germanium source includes GeH₄, and the boron containing source includes BCl₄. When the capping layer 16 is a polysilicon layer, the chemical elements 15 are doped using the silicon source and the boron containing source as reaction gas.

When SiGe is applied as the capping layer 16, the degradation of the metal layer 14 and the gate dielectric layer 13 may be prevented. The process temperature may be lowered to 450° C. or less by the presence of germanium in the SiGe, which prevents the degradation of the metal layer 14 and the gate dielectric layer 13. Furthermore, when SiGe is applied, the eWF may be controlled by boron and also controlled by concentration adjustment of boron and germanium.

According to the above descriptions, when the capping layer 16 is formed, the plurality of chemical elements 15 capable of controlling an eWF are doped. In particular, boron used as the chemical elements 15 reduces the eWF of the gate stacked structure of the NMOS. Here, the plurality of chemical elements 15 may have a concentration of 10²⁰ to 10²² atoms/cm².

Referring to FIG. 2D, a gate mask (not illustrated) is used to perform a gate patterning process. The gate patterning process is performed to sequentially etch the capping layer 16, the metal layer 14, the gate dielectric layer 13, and the interfacial layer 12.

Accordingly, the gate stacked structure is formed over the substrate 11. The gate stacked structure includes the gate dielectric layer 13, the metal layer 14, and the capping layer 16, which are sequentially stacked. The gate stacked structure further includes the interface layer 12 formed under the gate stacked structure 13. The gate stacked structure becomes a gate stacked structure of the NMOS. Furthermore, the capping layer 16 in the gate stacked structure has the plurality of chemical elements 15 doped therein.

After the gate patterning process, processes known in the art may be performed. For example, a source/drain formation process and so on may be performed. The source and drain 17 and 18 are doped with N-type impurities such as P or As. The N-type source and drain 17 and 18 are formed with the N-channel 19 interposed therebetween, and the gate stacked structure is formed over the N-channel 19.

Referring to FIG. 2E, annealing 20 is performed to activate the impurities doped into the source and drain 17 and 18. Here, the annealing 20 includes rapid thermal annealing (RTA). The annealing 20 may be performed at a temperature of 900˜1100° C.

The plurality of chemical elements 15 distributed within the capping layer 16 are concentrated at the interface with the metal layer 14 by annealing 20. That is, the plurality of chemical elements 15 are concentrated at the interface between the metal layer 14 and the capping layer 16. Since the chemical elements 15 include boron, the boron is concentrated at the interface between the metal layer 14 and the capping layer 16. The plurality of chemical elements 15 may have such a high density as to form a layer at the interface between the capping layer 16 and the metal layer 14. As such, when the plurality of chemical elements 15 are distributed at a high density, the eWF reduction effect is further increased. Here, the plurality of chemical elements 15 may have a concentration of 10²⁰ to 10²² atoms/cm².

The plurality of chemical elements 15 are concentrated at an interface with the metal layer 14, thereby reducing the eWF of the gate stacked structure.

Specifically, when boron operable as the chemical elements 15 is concentrated at the interface between the metal layer 14 and the capping layer 16, the eWF of the gate stacked structure may be reduced to control a threshold voltage for the NMOS. Here, as the chemical elements 15 are concentrated at an interface with the metal layer 14, an eWF (less than 4.5 eV) suitable for the NMOS may be obtained.

In the first embodiment of the present invention, an NMOS-type metal layer which is vulnerable to high temperature does not need to be used when the metal layer 14 is formed. That is, as the chemical elements 15 capable of controlling an eWF are formed, a metal layer having a midgap eWF (about 4.5 ev) which is easily fabricated is used. As such, although the metal layer 14 having a midgap eWF is used, the eWF reduction effect may be obtained through use of the plurality of chemical elements 15. Furthermore, when the metal layer having a midgap eWF is used in a state in which the thickness of the metal layer is reduced, the eWF reduction effect is further increased.

In the first embodiment of the present invention, since the threshold voltage may be controlled by the eWF reduction of the gate stacked structure, capping oxide for controlling the threshold voltage is not necessary. Therefore, production costs may be reduced.

FIG. 3 is a diagram illustrating a semiconductor device in accordance with a modification of the first embodiment of the present invention. The gate stacked structure NG may further include a low-resistance metal layer 21 formed over the capping layer 16. The low-resistance metal layer 21 may include W. The low-resistance metal layer 21 serves to lower gate resistance. The low-resistance metal layer 21 may include W, Ti, Co, Al, Ta, Hf, and a nitride or silicide of any of the foregoing elements. After the low-resistance metal layer 21 is formed, gate pattering is performed. Then, source/drain formation and annealing are performed.

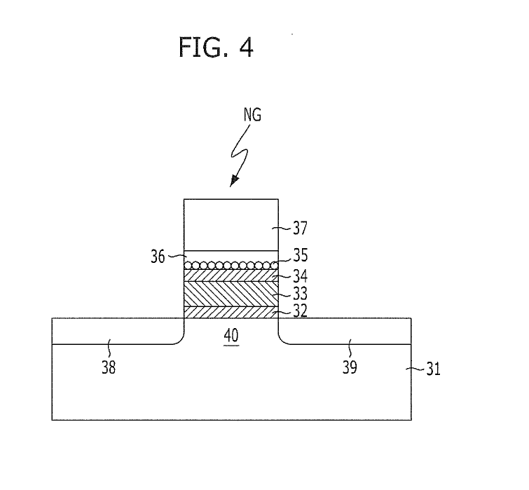

FIG. 4 is a diagram illustrating a gate stacked structure in accordance with a second embodiment of the present invention. FIG. 4 illustrates a gate stacked structure of an NMOS.

Referring to FIG. 4, a substrate 31 includes a transistor region. Here, the transistor region is where an NMOS is formed.

A gate stacked structure NG is formed over the substrate 31. The gate stacked structure NG includes a gate dielectric 33, a metal layer 34, a first capping layer 36, and a second capping layer 37, which are sequentially stacked. The gate stacked structure NG further includes an interfacial layer 32 between the gate dielectric layer 33 and the substrate 31. The interfacial layer 32 may include silicon oxide.

The substrate 31 may include substrates formed of silicon, germanium, and silicon germanium, but are not limited thereto. Here, the entire substrate 31 or a part of the substrate 31 may be placed under strain.

The gate stacked structure NG may be described in detail as follows.

First, the gate dielectric layer 33 includes a high-k dielectric. The high-k dielectric has a larger dielectric constant than the dielectric constant (about 3.9) of silicon oxide (SiO₂) which is generally used as a gate dielectric layer. Furthermore, the high-k dielectric has a considerably larger physical thickness and a smaller equivalent oxide thickness (EOT) than silicon oxide. The gate dielectric layer 33 includes a metal containing material such as metal oxide, metal silicate, or metal silicate nitride. The metal oxide includes oxide containing a metal such as Hf, Al, La, or Zr. The metal oxide may include hafnium oxide (HfO₂), aluminum oxide (Al₂O₃), lanthanum oxide (LaO₂), zirconium oxide (ZrO₂), or a combination thereof. The metal silicate includes silicate containing a metal such as Hf or Zr. The metal silicate may include hafnium silicate (HfSiO), zirconium silicate (ZrSiOₓ), or a combination thereof. The metal silicate nitride is a material obtained by containing nitrogen into metal silicate. According to example, the gate dielectric layer 33 may include metal silicate nitride. The metal silicate nitride may include hafnium silicate nitride (HfSiON). When the gate dielectric layer 33 is formed of metal silicate nitride, the dielectric constant may be increased, and crystallization may be suppressed during a subsequent thermal process. According to an example, the gate dielectric layer 33 may be formed of a material having a dielectric constant of 9 or more.

The metal layer 34 includes a metallic material such as metal, metal nitride, or metal carbide. For example, tungsten (W), tantalum (Ta), aluminum (Al), ruthenium (Ru), platinum (Pt), titanium nitride (TiN), tantalum nitride (TaN), titanium carbide (TiC), tantalum carbide (TaC), and a mixture thereof may be used. Furthermore, the metal layer 34 may include multi-layers of the above-described materials. The metal layer 34 becomes a metal gate electrode of the NMOS.

The first capping layer 36 and the second capping layer 37 serve to prevent the oxidation of the metal layer 34. The first and second capping layers 36 and 37 include polysilicon or SiGe. The first capping layer 36 includes a plurality of chemical elements 35 concentrated at the interface with the metal layer 34 (that is, has a higher concentration at the interface than another region of the metal layer 34). The plurality of chemical elements 35 serve to reduce an eWF of the gate stacked structure NG. The plurality of chemical elements 35 include boron. The plurality of chemical elements 35 may have such a high density as to form one layer at the interface between the first capping layer 36 and the metal layer 34. When the plurality of chemical elements 35 are distributed at such a high density, the eWF reduction effect is further increased. Here, the plurality of chemical elements 35 may have a concentration of 10²⁰ to 10²² atoms/cm³.

Inside the substrate 31, a source and drain 38 and 39 are formed. The source and drain 38 and 39 have N-type impurities implanted thereto. An N-channel 40 is formed in the substrate 31 under the gate stacked structure NG between the source and drain 38 and 39.

The gate stacked structure of FIG. 4 becomes a gate stacked structure of the NMOS. The gate stacked structure has a MIPS structure including a high-k dielectric material and a metal gate.

In the gate stacked structure NG, the plurality of chemical elements 35 are concentrated at the interface between the metal layer 34 and the first capping layer 36. The plurality of chemical elements 35 includes boron. The chemical elements 35 are concentrated at an interface with the metal layer 34 to thereby reduce the eWF of the gate stacked structure NG. Specifically, as boron is concentrated in the interface between the metal layer 34 and the first capping layer 36, the eWF of the gate stacked structure NG may be reduced to obtain an eWF suitable for the NMOS, and the threshold voltage may be controlled for the NMOS. Here, according to an example, the eWF suitable for the NMOS is less than 4.5 eV.

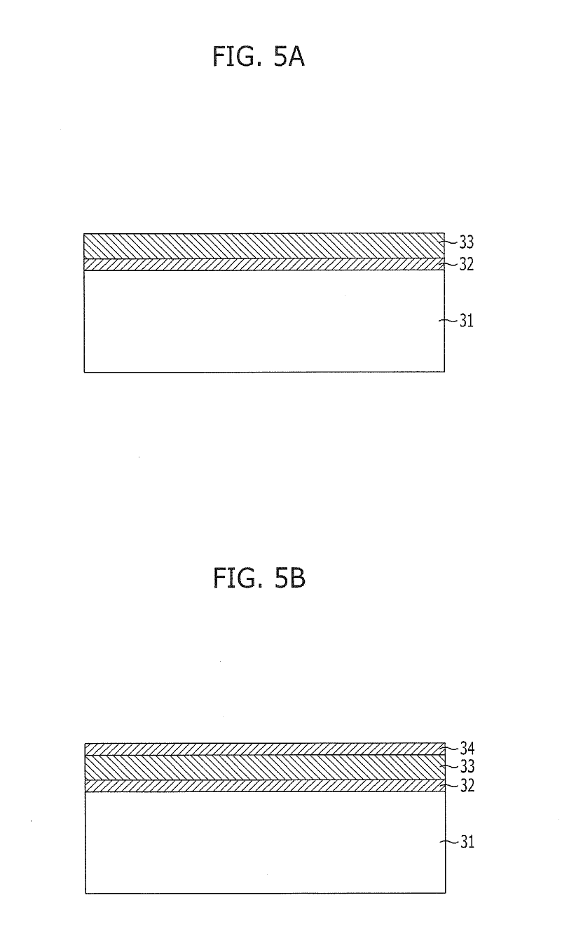

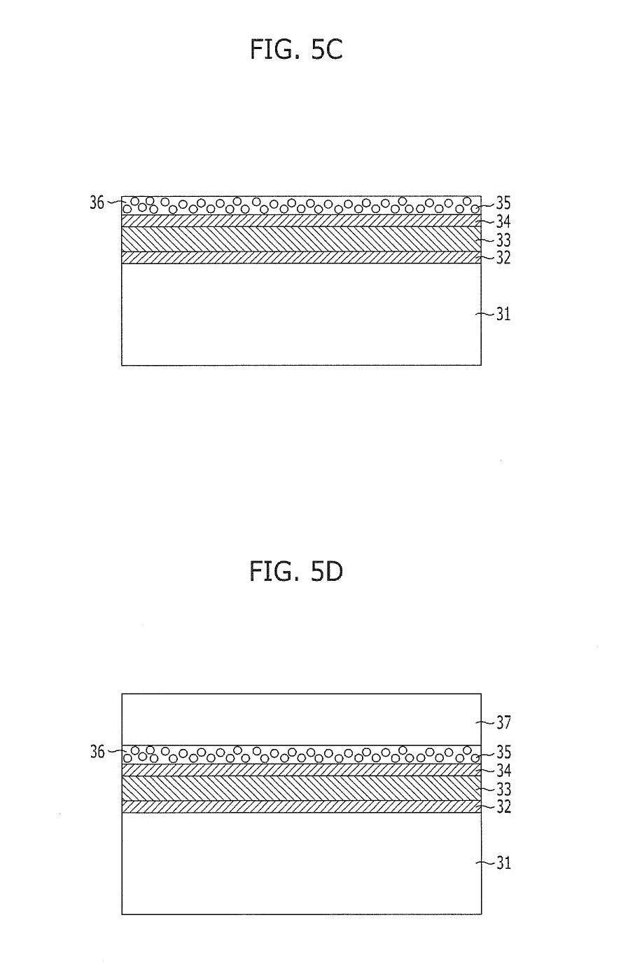

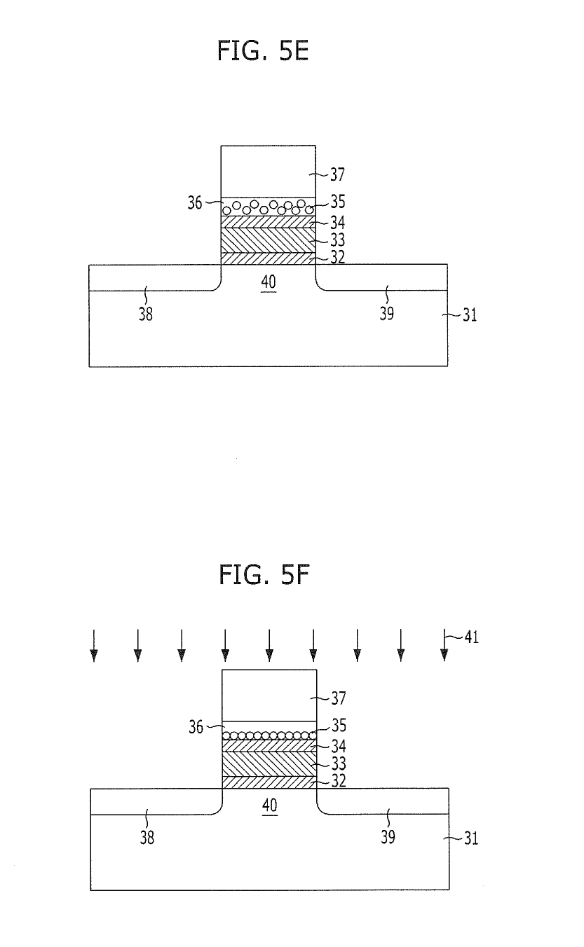

FIGS. 5A to 5F are diagrams illustrating a method for fabricating the semiconductor device in accordance with the second embodiment of the present invention. In the second embodiment of the present invention, an NMOS fabrication method will be described. The NMOS fabrication method is performed by a first gate process. The present invention is not limited to the NMOS, but may be applied to a method for fabricating an N-channel FET.

Referring to FIG. 5A, a substrate 31 is prepared. The substrate 31 is where an NMOS is formed. The substrate 31 may include substrates formed of silicon, germanium, and silicon germanium, but are not limited thereto. Here, the entire substrate 31 or a part of the substrate 31 may be placed under strain. Furthermore, although not illustrated, the substrate 31 may include a well which is formed through any reasonably suitable well formation process. Since the substrate 31 includes a region where the NMOS is formed, the well is a P-type well. In order to form a P-type well, P-type impurities such as boron may be implanted into the substrate 31. Furthermore, although not illustrated, an N-channel region may be formed through any reasonably suitable channel ion implantation process after the well formation process. In order to form the N-channel region, N-type impurities such as P or As may be implanted into the substrate 31.

Subsequently, a gate dielectric layer 33 is formed over the substrate 31. The gate dielectric layer 33 includes at least a high-k dielectric material. Furthermore, an interfacial layer 32 may be further formed between the substrate 31 and the gate dielectric layer 33.

The gate dielectric layer 33 is formed by the following method.

First, native oxide on the surface of the substrate 31 is removed through a cleaning process. The cleaning process is performed using a solution containing HF. As the cleaning process is performed, the native oxide on the surface of the substrate 31 is removed, and a dangling bond on the surface of the substrate 31 is also passivated with hydrogen. Therefore, the native oxide is suppressed from growing before a subsequent process is performed.

Subsequently, the interfacial layer 32 is formed. The interfacial layer 32 includes a dielectric material, for example, silicon oxide (SiO₂) or silicon oxynitride (SiON). The interfacial layer 32 serves to improve an interfacial characteristic between the substrate 31 and the gate dielectric layer 33, thereby enhancing electron mobility characteristics.

Next, the gate dielectric layer 33 is formed. The gate dielectric layer 33 includes a high-k dielectric material. The high-k dielectric material has a larger dielectric constant than the dielectric constant (about 3.9) of the silicon oxide (SiO₂) which is generally used as a gate dielectric layer. Furthermore, the high-k dielectric material has a considerably larger physical thickness and a smaller equivalent oxide thickness (EOT) than silicon oxide. The gate dielectric layer 33 may include a material having a larger dielectric constant than the interfacial layer 32.

The high-k dielectric material used as gate dielectric layer 33 includes a metal containing material such as metal oxide, metal silicate, or metal silicate nitride. The metal oxide includes oxide containing a metal such as Hf, Al, La, or Zr. The metal oxide may include hafnium oxide (HfO₂), aluminum oxide (Al₂O₃), lanthanum oxide (LaO₂), and zirconium oxide (ZrO₂) or a combination thereof. The metal silicate includes silicate containing a metal such as Hf or Zr. The metal silicate may include hafnium silicate (HfSiO) and zirconium silicate (ZrSiOₓ) or a combination thereof. The metal silicate nitride is a material obtained by a reaction of nitrogen with metal silicate. The metal silicate nitride may include hafnium silicate nitride (HfSiON). When the metal silicate nitride is used to form the gate dielectric layer 33, the dielectric constant may be increased, and crystallization may be suppressed during a subsequent thermal process. The formation process of the gate dielectric layer 33 may be performed by, for example, any reasonably suitable deposition technology for depositing a material. For example, the deposition technology may include chemical vapor deposition (CVD), low-pressure CVD (LPCVD), plasma-enhanced CVD (PECVD), metal-organic CVD (MOCVD), atomic layer deposition (ALD), plasma-enhanced ALD (PEALD), and so on. According to an example, the PEALD may be used to form a uniform thin film.

According to an example, the gate dielectric layer 33 may be formed of a material having a dielectric constant of 9 or more. Furthermore, the gate dielectric layer 33 may be formed of a Hf-based material. Here, the Hf-based material includes hafnium oxide (HfO₂), hafnium silicate (HfSiO), and hafnium silicate nitride (HfSiON).

Referring to FIG. 5B, a metal layer 34 is formed over the gate dielectric layer 33. The metal layer 34 becomes a metal gate electrode of the NMOS. The metal layer 34 includes a metallic material (that is, metal, metal nitride, or metal carbon nitride). For example, titanium nitride (TiN), titanium carbon nitride (TiCN), titanium aluminum nitride (TiAlN), titanium silicon nitride (TiSiN), tantalum nitride (TaN), tantalum carbon nitride (TaCN), tantalum silicon nitride (TaSiN), tantalum titanium nitride (TaTiN), titanium silicide (TiSi), hafnium nitride (HfN), and a mixture thereof may be used for the metal layer 34. Furthermore, the metal layer may 34 include multi-layers of the above-described materials. In the second embodiment of the present invention, TiN is used as the metal layer 34. The metal layer 34 is formed to a thickness of 0.1 nm-4 nm. When the metal layer 34 is formed to such a small thickness, eWF may be effectively reduced.

Referring to FIG. 5C, a first capping layer 36 containing a plurality of chemical elements 35 for controlling an eWF is formed over the metal layer 34. The first capping layer 36 serves as an oxidation prevention layer to prevent the oxidation of the metal layer 34.

The plurality of chemical elements 35 include elements to reduce an eWF. The first capping layer 36 includes a material preventing the oxidation of the metal layer 34. The first capping layer 36 includes a silicon containing layer. The first capping layer 36 includes polysilicon or silicon germanium (SiGe). Since the chemical elements 35 are elements to reduce the eWF, the first capping layer 36 includes polysilicon or SiGe doped with the plurality of chemical elements 35. The plurality of chemical elements 15 may include boron. The plurality of chemical elements 35 may have a concentration of 10²⁰ to 10²² atoms/cm².

Therefore, the first capping layer 36 includes boron-dope polysilicon or boron-doped SiGe.

The plurality of chemical elements 35 may be in-situ doped when the capping layer 36 is formed. For example, when the first capping layer 36 includes SiGe, boron containing gas is used to in-situ dope boron during deposition of SiGe for the first capping layer 36.

The first capping layer 36 is deposited at a temperature of 450° C. or less in a furnace. During the deposition of the first capping layer 36, a silicon source, a germanium source, or a boron containing source may be used as reaction gas. The silicon source includes SiH₄, the germanium source includes GeH₄, and the boron containing source includes BCl₄. When the first capping layer 36 is a polysilicon layer, the chemical elements 35 are doped using the silicon source and the boron containing source as reaction gas.

According to the above descriptions, when the first capping layer 36 is formed, the plurality of chemical elements 35 capable of controlling the eWF of the gate stacked structure are in-situ doped.

When a SiGe layer is applied as the first capping layer 36, the degradation of the metal layer 34 and the gate dielectric layer 33 is prevented. The process temperature may be lowered to 450° C. or less by the presence of germanium in the SiGe layer, which prevents the degradation of the metal layer 34 and the gate dielectric layer 33. Furthermore, when the SiGe layer is applied, the eWF may be controlled by boron and also controlled by concentration adjustment of boron and germanium.

Referring to FIG. 5D, a second capping layer 37 is formed over the first capping layer 36. The first and second capping layer 36 and 37 may be formed of the same material. However, the second capping layer 37 is not doped with the chemical elements 35 and thus does not include a higher concentration of the chemical elements 35 at an interface between the second capping layer and the first capping layer 36 than another region of the second capping layer 37. The second capping layer 37 includes a material to prevent the oxidation of the metal layer 34. The second capping layer 37 includes a silicon containing layer. The second capping layer 37 includes polysilicon or SiGe. The second capping layer 37 includes undoped polysilicon or undoped SiGe.

The second capping layer 37 is deposited at a temperature of 450° C. or less in a furnace. During the deposition of the second capping layer 37, a silicon source and a germanium source are used as reaction gas. The silicon source includes SiH₄, and the germanium source includes GeH₄. When the second capping layer 37 is a polysilicon layer, the silicon source is used as reaction gas to form the second capping layer 37.

Meanwhile, the second capping layer 37 may be doped with impurities such as P by ion implantation, after the deposition. At this time, since the impurities are implanted by the ion implantation, they are uniformly distributed in the second capping layer 37.

In accordance with the second embodiment of the present invention, the first capping layer 36 is formed between the metal layer 34 and the second capping layer 37. The first capping layer 36 includes the plurality of chemical elements 35. The plurality of chemical elements 35 reduce the eWF of the gate stacked structure.

Although not illustrated, a low-resistance metal layer may be formed over the second capping layer 37, in accordance with a modification of the second embodiment of the present invention. The low-resistance metal layer may include W. The low-resistance metal layer serves to reduce gate resistance. The low-resistance metal layer may include W, Ti, Co, Al, Ta, Hf, and nitride or silicide of any of the foregoing elements.

Referring to FIG. 5E, a gate mask (not illustrated) is used to perform a gate patterning process. The gate patterning process is performed to sequentially etch the second capping layer 37, the first capping layer 36, the metal layer 34, the gate dielectric layer 33, and the interfacial layer 32.

Accordingly, the gate stacked structure is formed over the substrate 31. The gate stacked structure includes the gate dielectric layer 33, the metal layer 34, the first capping layer 36, and the second capping layer 37, which are sequentially stacked. The gate stacked structure further includes the interface layer 32 formed under the gate dielectric layer 33. The gate stacked structure becomes a gate stacked structure of the NMOS. Furthermore, the gate stacked structure includes the first capping layer 36 doped with the plurality of chemical elements 15.

After the gate patterning process, processes known in the art may be performed. For example, a source/drain formation process and so on may be performed. The source and drain 38 and 39 are doped with N-type impurities such as P or As. The N-type source and drain 38 and 39 are formed with an N-channel 40 interposed therebetween, and the gate stacked structure NG is formed over the N-channel 40.

Referring to FIG. 5F, annealing 41 is performed to activate the impurities doped into the source and drain 38 and 39. Here, the annealing 41 includes rapid thermal annealing (RTA). The annealing 41 may be performed at a temperature of 900-1100° C.

The plurality of chemical elements 35 distributed within the first capping layer 36 are concentrated at the interface with the metal layer 34 by the annealing 41. That is, the plurality of chemical elements 35 are concentrated at an interface with the metal layer 34. Since the chemical elements 35 include boron, the boron is concentrated at an interface with the metal layer 34. The plurality of chemical elements 35 may have such a high density as to form one layer at the interface between the first capping layer 36 and the metal layer 34. As such, when the plurality of chemical elements 35 are distributed at a high density, the eWF reduction effect is further increased. Here, the plurality of chemical elements 35 may have a concentration of 10²⁰ to 10²² atoms/cm².

The plurality of chemical elements 35 are concentrated at an interface with the metal layer 34, thereby reducing the eWF of the gate stacked structure.

Specifically, when boron as the chemical elements 35 is concentrated at an interface with the metal layer 34, the eWF of the gate stacked structure may be reduced to control a threshold voltage for the NMOS. In addition, as the chemical elements 35 are concentrated at an interface with the metal layer 34, an eWF (less than 4.5 eV) suitable for the NMOS may be obtained.

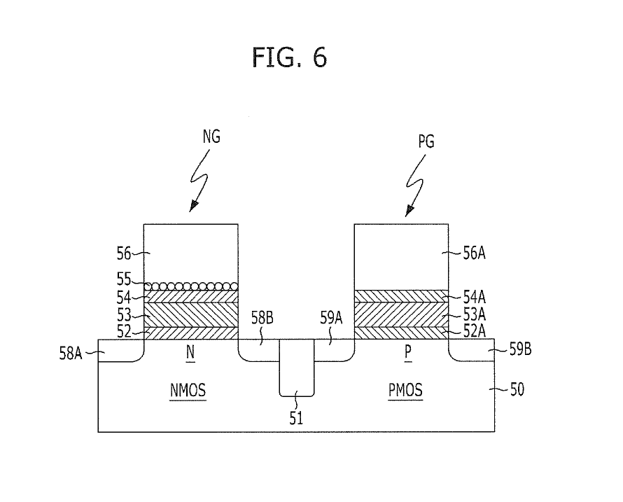

FIG. 6 is a diagram illustrating a CMOS integrated circuit including the NMOS in accordance with the embodiments of the present invention.

Referring to FIG. 6, a substrate 50 includes a first region NMOS and a second region PMOS, which are isolated by an isolation region 51. The first region is where an NMOS is formed, and the second region is where a PMOS is formed. The substrate 50 may include substrates formed of silicon, germanium, and silicon germanium, but are not limited thereto. Furthermore, the entire substrate 50 or a part of the substrate 50 may be placed under strain.

A first gate stacked structure NG is formed over the substrate 50 of the first region NMOS, and a second gate stacked structure PG is formed over the substrate 50 of the second region PMOS.

The first gate stacked structure NG includes a gate dielectric layer 53, a metal layer 54, a capping layer 56, and a low-resistance metal layer 57, which are sequentially stacked. A plurality of chemical elements 55 are concentrated at an interface with the metal layer 54. An N-channel N is formed in the substrate 50 under the first gate stacked structure NG. The first gate stacked structure NG further includes an interfacial layer 52 between the gate dielectric layer 53 and the substrate 50. The interfacial layer 52 may include silicon oxide.

The second gate structure PG includes a gate dielectric layer 53A, a metal layer 54A, a capping layer 56A, and a low-resistance metal layer 57A, which are sequentially stacked. A P-channel P is formed in the substrate 50 under the second gate stacked structure PG. The second gate stacked structure PG further includes an interfacial layer 52A between the gate dielectric layer 53A and the substrate 50. The interfacial layer 52A may include silicon oxide.

The first and second gate stacked structures NG and PG may be described in detail as follows.

First, the gate dielectric layers 53 and 53A include a high-k dielectric material. The high-k dielectric material has a larger dielectric constant than the dielectric constant (about 3.9) of silicon oxide (SiO₂) which is generally used as a gate dielectric layer. Furthermore, the high-k dielectric has a considerably larger physical thickness and a smaller equivalent oxide thickness (EOT) than silicon oxide. The gate dielectric layers 53 and 53A includes a metal containing material such as metal oxide, metal silicate, or metal silicate nitride. The metal oxide includes oxide containing a metal such as Hf, Al, La, or Zr. The metal oxide may include hafnium oxide (HfO₂), aluminum oxide (Al₂O₃), lanthanum oxide (LaO₂), zirconium oxide (ZrO₂), or a combination thereof. The metal silicate includes silicate containing a metal such as Hf or Zr. The metal silicate may include hafnium silicate (HfSiO), zirconium silicate (ZrSiOₓ), or a combination thereof. The metal silicate nitride is a material obtained by containing nitrogen into metal silicate. According to an example, the gate dielectric layers 53 and 53A may include metal silicate nitride. The metal silicate nitride may include hafnium silicate nitride (HfSiON). When the gate dielectric layers 53 and 53A are formed of metal silicate nitride, the dielectric constant may be increased, and crystallization may be suppressed during a subsequent thermal process. According to an example, the gate dielectric layers 53 and 53A may be formed of a material having a dielectric constant of 9 or more.

The metal layers 54 and 54A include a metallic material such as metal, metal nitride, or metal carbide. For example, tungsten (W), tantalum (Ta), aluminum (Al), ruthenium (Ru), platinum (Pt), titanium nitride (TiN), tantalum nitride (TaN), titanium carbide (TIC), tantalum carbide (TaC), and a mixture thereof may be used. Furthermore, the metal layers 54 and 54A may include multi-layers of the above-described materials. The metal layers 54 and 54A become metal gate electrodes of the NMOS and the PMOS.

The capping layers 56 and 56A serve to prevent the oxidation of the metal layers 54 and 54A. The capping layers 56 and 56A include polysilicon or SiGe. In the first gate stacked structure NG, the capping layer 56 includes a plurality of chemical elements 55 concentrated at the interface with the metal layer 54. The plurality of chemical elements 55 serve to reduce an eWF of the first gate stacked structure NG. The plurality of chemical elements 55 include boron. Here, the plurality of chemical elements 55 may have a concentration of concentration of 10²⁰ to 10²² atoms/cm³.

Inside the substrate 50 of the first region NMOS, an N-type source and drain 58A and 58B are formed. The N-type source and drain 58A and 58B have N-type impurities implanted therein. An N-channel N is formed in the substrate 50 under the first gate stacked structure NG between the N-type source and drain 58A and 58B.

Inside the substrate 50 of the second region PMOS, a P-type source and drain 59A and 59B are formed. The P-type source and drain 59A and 59B have P-type impurities implanted thereto. A P-channel P is formed in the substrate 50 under the second gate stacked structure PG between the P-type source and drain 59A and 59B.

Referring to FIG. 6, the first gate stacked structure NG becomes a gate stacked structure of the NMOS, and the second gate stacked structure PG becomes a gate stacked structure of the PMOS. The first and second gate stacked structures NG and PG have a MIPS structure including a high-k dielectric material and a metal gate.

In the first gate stacked structure, the plurality of chemical elements 55 are concentrated at the interface between the metal layer 54 and the capping layer 56. The plurality of chemical elements 55 include boron. The chemical elements 55 are concentrated at an interface with the metal layer 54, thereby reducing the eWF of the first gate stacked structure NG. Accordingly, the threshold voltage may be controlled for the NMOS.

Meanwhile, although not illustrated, a method for controlling the threshold voltage of the PMOS may be performed by referring to well-known methods. For example, the methods may include a method of implanting germanium into a channel and a method of applying a metal having a WF suitable for the PMOS as a metal layer.

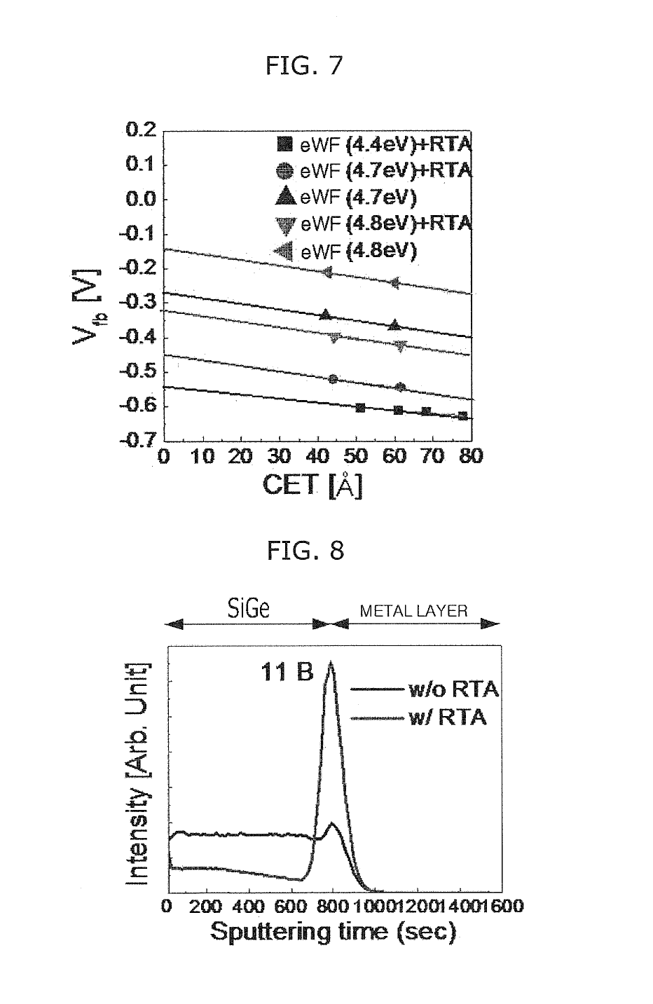

FIG. 7 is a graph showing variations in a flat band voltage in accordance with the embodiments of the present invention. FIG. 7 shows a plot of a flat band voltage V_{fb} and a capacitance equivalent thickness (CET). FIG. 7 shows a result obtained by forming a SiGe layer doped with boron over a metal layer. Three specimens 1 to 3 having eWFs of 4.4 eV, 4.7 eV, and 4.8 eV, respectively, were fabricated as gate stacked structures.

Referring to FIG. 7, it can be seen that the flat band voltages V_{fb} of the specimens 1 to 3 are varied, when rapid thermal annealing (RTA) is performed. Here, it is well known that a threshold voltage Vt is varied in response to a variation in the flat band voltage V_{fb}. Therefore, when the methods in accordance with the embodiments of the present invention are applied, the threshold voltage may be controlled for the NMOS.

TABLE 1

| | eWF before annealing | eWF after annealing |
|---|---|---|
| Specimen 1 | 4.4 eV | 4.2 eV |
| Specimen 2 | 4.7 eV | 4.5 eV |
| Specimen 3 | 4.8 eV | 4.6 eV |

Table 1 comparatively shows the eWFs before annealing with the eWFs after annealing.

According to the Table 1, the eWFs of the specimens 1 to 3 were reduced by about 0.2 eV, after annealing.

Through Table 1, it can be seen that, although the gate stacked structure of the NMOS uses a metal having a midgap WF (about 4.5 eV) as the metal layer, the eWF is reduced by about 0.2 eV because boron is concentrated at an interface with the metal layer in the gate stacked structure. Therefore, although a metal having a well-known midgap WF is used as a metal gate electrode, a WF suitable for the NMOS may be obtained.

FIG. 8 is a graph showing a secondary ion mass spectroscopy (SIMS) analysis result which is obtained after an annealing process is performed on the gate stacked structures in accordance with the embodiments of the present invention. FIG. 8 shows a result obtained by forming a SiGe layer doped with boron over the metal layer.

Referring to FIG. 8, it can be seen that boron 11B is uniformly distributed in the SiGe layer before annealing (w/o RTA), but is heavily concentrated at the interface between the SiGe layer and the metal layer after annealing (w/RTA). Here, the boron may have a concentration of 10²⁰ to 10²² atoms/cm². The annealing may be performed at a temperature of 900˜1,100° C. FIG. 8 shows a case in which RTA is applied at a temperature of 1,000° C.

The NMOS in accordance with the embodiments of the present invention may be applied to a CMOS integrated circuit. The CMOS integrated circuit has at least one NMOS and PMOS, and each of the NMOS and PMOS has a gate stacked structure including a high-k dielectric material and a metal gate. The gate stacked structure of the NMOS includes the gate stacked structures in accordance with the embodiments of the present invention.

The NMOS in accordance with the embodiment of the present invention may be applied to various semiconductor devices. The semiconductor devices may include a dynamic random access memory (DRAM). Without being limited thereto, the semiconductor devices may include a static random access memory (SRAM), a flash memory, a ferroelectric random access memory (FeRAM), magnetic random access memory (MRAM), and a phase change random access memory (PRAM).

Exemplary products of the above-described semiconductor device may include a graphic memory having various specifications and a mobile memory as well as a computing memory used for a desktop computer, a notebook computer, and a server. Furthermore, the semiconductor device may be used for portable storage media such as memory stick, MMC, SD, CF, xD picture card, and USB flash device and also various digital applications such as MP3, PMP, digital camera, camcorder, and mobile phone. Furthermore, the semiconductor device may be applied to a multi-chip package (MCP), a disk on chip (DOC), and an embedded device. Furthermore, the semiconductor device may be applied to a CMOS image sensor (CIS) and applied to various other fields such as camera phone, web camera, and medical small-sized imaging device.

In accordance with the embodiments of the present invention, the plurality of chemical elements are distributed over the metal layer in the gate stacked structure including the high-k dielectric material and the metal layer, thereby reducing the eWF of the gate stacked structure. Therefore, an appropriate threshold voltage may be obtained.

Furthermore, the threshold voltage of the NMOS may be controlled without necessarily using a metal layer which is vulnerable to a high-temperature process and adds manufacturing complexity and without necessarily using capping oxide that adds high manufacturing costs.

While the present invention has been described with respect to the specific embodiments, it will be apparent to those skilled in the art that various changes and modifications may be made without departing from the spirit and scope of the invention as defined in the following claims.

What is claimed is:

1. A semiconductor device comprising:
a gate stacked structure comprising a gate dielectric layer formed over a semiconductor substrate, a metal layer formed over the gate dielectric layer, and a capping layer formed over the metal layer,
wherein the capping layer includes a chemical element with a higher concentration at an interface between the capping layer and the metal layer than another region of the capping layer and the chemical element is operable to control an effective work function (eWF) of the gate stacked structure.

2. The semiconductor device of claim 1, wherein the chemical element comprises boron.

3. The semiconductor device of claim 1, wherein the capping layer comprises polysilicon or silicon germanium (SiGe).

4. The semiconductor device of claim 1, further comprising an interfacial layer formed between the gate dielectric layer and the semiconductor substrate,
wherein the gate dielectric layer has a larger dielectric constant than the interfacial layer.

5. The semiconductor device of claim 4, wherein the interfacial layer comprises silicon oxide and the gate dielectric layer has a larger dielectric constant than the silicon oxide.

6. The semiconductor device of claim 1, wherein the gate stacked structure becomes a gate stacked structure of an N-channel metal-oxide-semiconductor (NMOS).

7. A semiconductor device comprising an N-channel metal-oxide-semiconductor (NMOS) gate stacked structure and a P-channel metal-oxide-semiconductor (PMOS) gate stacked structure which are isolated from each other and formed over a semiconductor substrate,
wherein the NMOS gate stacked structure comprises a gate dielectric layer, a metal layer over the gate dielectric layer, a capping layer over the metal layer, the capping layer includes a chemical element having a higher concentration at an interface between the capping layer and the metal layer than another region of the capping layer, and the chemical element is operable to control an effective work function (eWF) of the NMOS gate stacked structure.

8. The semiconductor device of claim 7, wherein the chemical element comprises boron.

9. The semiconductor device of claim 7, wherein the capping layer comprise polysilicon or SiGe.

10. The semiconductor device of claim 7, further comprising an interfacial layer formed between the gate dielectric layer and the semiconductor substrate,
wherein the gate dielectric layer has a larger dielectric constant than the interfacial layer.

11. The semiconductor device of claim 10, wherein the interfacial layer comprises silicon oxide and the gate dielectric layer has a larger dielectric constant than the silicon oxide.

12. An N-channel metal-oxide-semiconductor (NMOS) comprising:
a semiconductor substrate having an N-channel;
a gate stacked structure comprising a gate dielectric layer formed over the N-channel, a metal layer formed over the gate dielectric layer, and a capping layer formed over the metal layer; and
a first capping layer including a higher concentration of boron at an interface between the metal layer and the capping layer than another region of the capping layer, wherein the boron is operable to control an effective work function (eWF) of the gate stacked structure.

13. The semiconductor device of claim 12, further comprising a second capping layer formed on the first capping layer, wherein the second capping layer does not include a higher concentration of the chemical element at an interface between the first and second capping layers than another region of the second capping layer.

14. The semiconductor device of claim 12, further comprising a metal layer formed over the first capping layer.

15. A method for fabricating a semiconductor device, comprising:
forming a gate dielectric layer over a semiconductor substrate;
forming a metal layer over the gate dielectric layer;
forming a capping layer over the metal layer, the capping layer including a chemical element for controlling an effective work function (eWF);
forming a gate stacked structure by etching the capping layer, the metal layer, and the gate dielectric layer; and
performing annealing to form a higher concentration of the chemical element at an interface between the capping layer and the metal layer than another region of the capping layer.

16. The method of claim 15, wherein the chemical element comprises boron.

17. The method of claim 15, wherein the annealing is performed by rapid thermal annealing (RTA).

18. The method of claim 15, wherein the forming of the capping layer comprises:
forming a first capping layer doped with the chemical element over the metal layer; and
forming a second capping layer over the first capping layer.

19. The method of claim 15, wherein the forming of the capping layer comprises forming a SiGe layer over the metal layer, the SiGe layer being in-situ doped with boron operable as the chemical element.

20. The method of claim 15, wherein the capping layer comprises polysilicon or SiGe.

21. The method of claim 15, further comprising forming an interfacial layer between the gate dielectric layer and the semiconductor substrate,
wherein the gate dielectric layer has a larger dielectric constant than the interfacial layer.

22. The method of claim 21, wherein the interfacial layer comprises silicon oxide and the gate dielectric layer has a larger dielectric constant than the silicon oxide.

23. A method for fabricating a semiconductor device, comprising:
forming a gate dielectric layer over a semiconductor substrate;
forming a metal layer over the gate dielectric layer;
forming a capping layer over the metal layer, wherein the capping layer includes a chemical element for controlling an effective work function (eWF);
forming a gate stacked structure by etching the capping layer, the metal layer, and the gate dielectric layer;
forming a source/drain by implanting impurities into the substrate; and
performing annealing to form a higher concentration of the chemical element at an interface between the capping layer and the metal layer than another region of the capping layer.

24. The method of claim 23, wherein the chemical element comprises boron.

25. The method of claim 23, wherein the annealing is performed by rapid thermal annealing (RTA).

26. The method of claim 23, wherein the forming of the capping layer comprises:
forming a first capping layer doped with the chemical element over the metal layer; and
forming a second capping layer over the first capping layer.

27. The method of claim 23, wherein the forming of the capping layer comprises forming a SiGe layer over the metal layer, the SiGe layer being in-situ doped with boron operable as the chemical element.

28. The method of claim 23, wherein the capping layer comprises polysilicon or SiGe.

29. The method of claim 23, further comprising forming an interfacial layer between the gate dielectric layer and the semiconductor substrate,
wherein the gate dielectric layer has a larger dielectric constant than the interfacial layer.

30. The method of claim 29, wherein the interfacial layer comprises silicon oxide and the gate dielectric layer has a larger dielectric constant than the silicon oxide.

31. The method of claim 23, wherein the chemical element comprises boron and the gate stacked structure becomes a gate stacked structure of an N-channel metal-oxide-semiconductor (NMOS).
